(19) United States
(12) Patent Application Publication
(10) Pub. No.: US 2002/0162679 A1
(43) Pub. Date: Nov. 7, 2002

(54) Package level pre-applied underfills for thermo-mechanical reliability enhancements of electronic assemblies

(76) Inventors: Nael Hannan, Keller, TX (US); Viswamadham Puligandla, Flower Mound, TX (US); Steven Dunford, Lewisville, TX (US); Pekka Rautila, Salo (FI)

Correspondence Address: STEVEN A. SHAW, NOKIA, INC., 6000 CONNECTION DRIVE, MD 1-4-755, IRVING, TX, 75039, US

(21) Appl. No.: 10/134,879

(22) Filed: Apr. 29, 2002

Related U.S. Application Data
(60) Provisional application No. 60/288,611, filed on May 4, 2001.
(60) Provisional application No. 60/363,068, filed on Mar. 11, 2002.

(51) Int. Cl. H01L 23/02

(52) U.S. Cl. 174/52.4

(57) ABSTRACT

Surface mount packages having pre-applied underfill thereon and methods of fabricating and using such packages are provided. Supplying customers with packages having pre-applied underfill enhances the thermal and mechanical reliability of surface mount packages and also, mitigates the customers' needs for additional cost, tooling, man-power, and process operations relating to the application and curing of underfill material.

### REFERENCE TO RELATED APPLICATIONS

This application claims the benefit of U.S. Provisional Patent Application Serial No. 60/288,611, which was filed on May 4, 2001, entitled PACKAGE LEVEL PRE-APPLIED UNDERFILLS FOR THERMO-MECHANICAL RELIABILITY ENHANCEMENTS OF ELECTRONIC ASSEMBLIES, and the benefit of U.S. Provisional Patent Application Serial No. 60/363,068, which was filed on Mar. 11, 2002, entitled PACKAGE LEVEL PRE-APPLIED UNDERFILLS FOR THERMO-MECHANICAL RELIABILITY ENHANCEMENTS OF ELECTRONIC ASSEMBLIES.

### TECHNICAL FIELD

The present invention relates to packaging of an electronic component and, more particularly, to electronic component packages having pre-applied underfill and methods of fabricating and using electronic component packages having pre-applied underfill.

### BACKGROUND OF THE INVENTION

Microelectronic devices contain millions of electronic circuit components, mainly transistors assembled in integrated circuit (IC) chips, but also resistors, capacitors, and other components. These electronic components are typically interconnected to form circuits, and are eventually connected to and supported on a carrier or substrate, such as a printed wiring board (PWB) or printed circuit board (PCB).

An IC component can comprise a single bare chip, a single encapsulated chip, or an encapsulated package of multiple chips. The single bare chip can be attached to a lead frame, which in turn, is encapsulated and attached to a PWB or PCB, or it can be directly attached to the PWB or PCB.

Whether the component is a bare chip connected to a lead frame, or a package connected to a printed wiring board or other substrate, the connections are made between electrical terminations on the electronic component and corresponding electrical terminations on the substrate. One method for making these connections utilizes attachment material applied in bumps, or balls, to the component or substrate terminals. The terminals are aligned and contacted together and the resulting assembly is heated to reflow the attachment material and solidify the connection.

During subsequent manufacturing steps, the electronic assembly is subjected to cycles of elevated and lowered temperatures. Due to differences in coefficient of thermal expansion (CTE) for the electronic component, the interconnect material, and the substrate respectively, this thermal cycling can stress the components of the assembly and cause failure. In order to mitigate failure caused by CTE mismatch, the gap between the component and the substrate is often filled with a polymeric encapsulant, hereinafter referred to as “underfill”, to reinforce the interconnect and to absorb some of the stress of thermal cycling.

The underfill encapsulation can take place after reflow of the attachment, or interconnect, material, or it may occur concurrently with the reflow. If underfill encapsulation takes place after the reflow of the interconnect, a measured amount of underfill encapsulant material will be dispensed along one or more peripheral sides of the electronic assembly and capillary action within the component-to-substrate gap draws the material inward. The substrate may be preheated, if needed, to achieve the desired level of encapsulant viscosity for the optimum capillary action. After the gap is filled, additional underfill may be dispensed along the complete assembly periphery to facilitate mitigation of stress concentrations and prolong fatigue life of the assembled structure. The underfill is subsequently cured to reach desired final properties.

If underfill encapsulation is to take place concurrently with the reflow of the interconnect material, the underfill is applied to the substrate, such as a PWB or PCB; then terminals on the component and substrate are aligned and contacted and the assembly is heated to reflow the interconnect material. During this heating process, curing of the underfill occurs concurrently with the reflow of the interconnect material.

However, the methods described above pose significant issues for customers employing surface mount packages for attachment to a substrate. Because of the need to mitigate stresses produced by CTE mismatch between the package and the substrate, additional process steps are often required to perform underfill and curing operations. This, in turn leads to, additional tools, man-power, and cost. Furthermore, personnel may be exposed to hazardous fumes or vapors created by the underfill operation which can cause allergic and other health issues.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor delineate the scope of the invention. Its sole purpose is to present some concepts of the invention in a simplified form as a prelude to the more detailed description that is presented later.

The present invention relates to systems and methods for surface mount packages having pre-applied underfill thereon. Such packages provide enhanced thermo-mechanical reliability. The various packaging schemes and methodologies described herein mitigate a need for underfill processes to be carried out at an assembly location where chip package integration is performed.

The surface mount packages of the present invention have attachment material disposed, deposited, or otherwise placed thereon. The attachment material can be of any form and type to facilitate forming an electrical connection with a substrate. It is to be appreciated herein that the term “substrate” is intended to encompass any suitable surface that a surface mount package might be applied to. For example, a printed circuit board (PCB), or printed wiring board (PWB), would be considered a substrate within the scope of the subject invention. Underfill material is then applied to at least a portion of the substrate prior to shipment.

To the accomplishment of the foregoing and related ends, certain illustrative aspects of the invention are described herein in connection with the following description and the annexed drawings. These aspects are indicative, however, of but a few of the various ways in which the principles of the invention may be employed and the present invention is intended to include all such aspects and their equivalents. Other advantages and novel features of the invention will become apparent from the following detailed description of the invention when considered in conjunction with the drawings.

### BRIEF DESCRIPTION OF THE DRAWINGS

FIG. 1 illustrates a side view of an electronic component with a preapplied underfill in accordance with an aspect of the present invention.

FIG. 2 illustrates a top view of an edge locking type underfill configuration in accordance with an aspect of the present invention.

FIG. 3 illustrates a perspective view of the edge locking type underfill configuration of FIG. 2 in accordance with an aspect of the present invention.

FIG. 4 illustrates a top view of another edge locking type underfill configuration in accordance with an aspect of the present invention.

FIG. 5 illustrates a perspective view of the edge locking type underfill configuration of FIG. 4 in accordance with an aspect of the present invention.

FIG. 6 illustrates a top view of another edge locking type underfill configuration in accordance with an aspect of the present invention.

FIG. 7 illustrates a perspective view of the edge locking type underfill configuration of FIG. 6 in accordance with an aspect of the present invention.

FIG. 8 illustrates a top view of another edge locking type underfill configuration in accordance with an aspect of the present invention.

FIG. 9 illustrates a perspective view of the edge locking type underfill configuration of FIG. 8 in accordance with an aspect of the present invention.

FIG. 10 illustrates a top view of dam and fill type underfill configuration in accordance with an aspect of the present invention.

FIG. 11 illustrates a perspective view of the dam and fill type underfill configuration of FIG. 10 in accordance with an aspect of the present invention.

FIG. 12 illustrates a top view of another dam and fill type underfill configuration in accordance with an aspect of the present invention.

FIG. 13 illustrates a perspective view of the dam and fill type underfill configuration of FIG. 12 in accordance with an aspect of the present invention.

FIG. 14 illustrates a side view of an electronic component attached to a substrate by a plurality of solder balls and underfill in accordance with an aspect of the present invention.

FIG. 15 illustrates a side view of another underfill configuration in accordance with an aspect of the present invention.

FIG. 16 illustrates a side view of the electronic component and underfill configuration of FIG. 15 attached to a substrate in accordance with an aspect of the present invention.

FIG. 17 illustrates a top view of an electronic component with encapsulated lead wires in accordance with an aspect of the present invention.

FIG. 18 illustrates a partial side view of underfill applied around an outside of a TSOP in accordance with an aspect of the present invention.

FIG. 19 illustrates a partial side view of a dam and fill type underfill applied in a TSOP application in accordance with an aspect of the present invention.

FIG. 20 illustrates a partial side view of underfill applied around an outside of a J-lead in accordance with an aspect of the present invention.

FIG. 21 illustrates a partial side view of a dam and fill type underfill applied in a J-lead application in accordance with an aspect of the present invention.

FIG. 22 illustrates a perspective view of an electronic component with lead wires encapsulated with underfill in accordance with an aspect of the present invention.

FIG. 23 illustrates a perspective view of an electronic component with lead wires encapsulated with underfill in accordance with an aspect of the present invention.

FIG. 24 illustrates a film application in accordance with an aspect of the present invention.

FIG. 25 illustrates a side view of a film underfill in accordance with an aspect of the present invention.

FIG. 26 illustrates a film application including a punching operation in accordance with an aspect of the present invention.

FIG. 27 illustrates a side view of a film underfill having punched holes in accordance with an aspect of the present invention.

FIG. 28 illustrates an electronic component having a pre-applied underfill in accordance with an aspect of the present invention.

FIG. 29 illustrates an electronic component being aligned with a substrate in accordance with an aspect of the present invention.

FIG. 30 illustrates an electronic component attached to a substrate in accordance with an aspect of the present invention.

FIG. 31 illustrates a methodology of fabricating a surface mount package with pre-applied underfill in accordance with an aspect of the present invention.

FIG. 32 illustrates a methodology of using a surface mount package with pre-applied underfill in accordance with an aspect of the present invention.

### DETAILED DESCRIPTION OF INVENTION

The present invention relates to systems and methods for electronic components having pre-applied underfills in order to enhance thermal and mechanical reliability of surface mount packages. The present invention will now be described with reference to the drawings, wherein like reference numerals are used to refer to like elements throughout. In the following description, for purposes of explanation, numerous specific details are set forth in order to provide a thorough understanding of the present invention. It may be evident, however, that the present invention may be practiced without these specific details. In other instances, well-known structures and devices are shown in block form in order to facilitate describing the present invention.

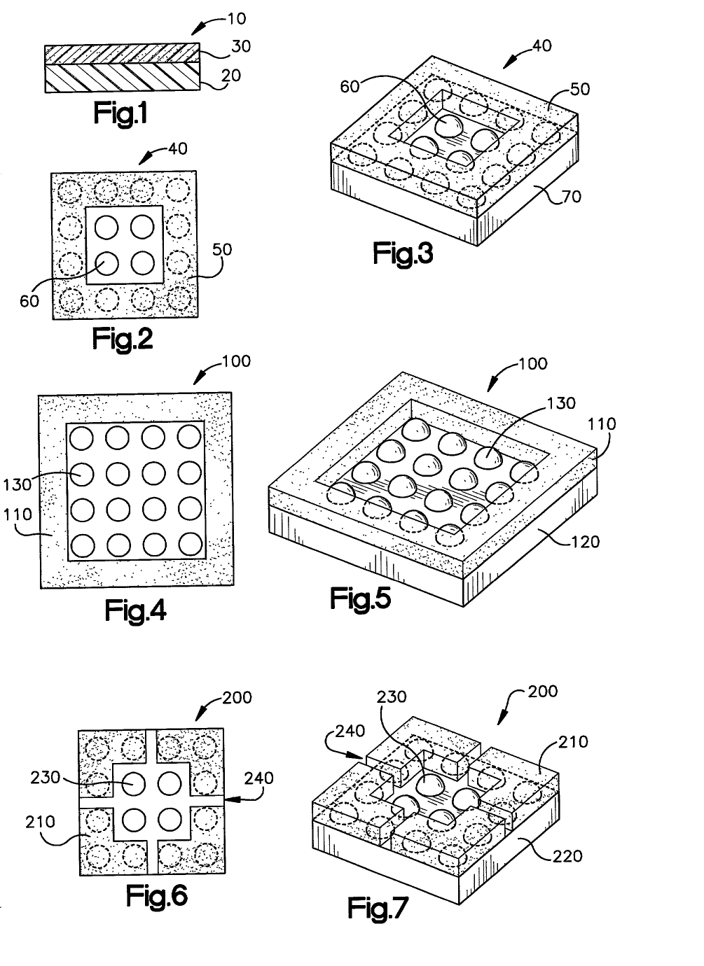

FIG. 1 illustrates an example of a surface mount package 10 comprising an electronic component 20 and an underfill material 30 applied thereon. The surface mount package 10 can be a variety of types, such as for example, Ball Grid Array, gull wing, J-leaded, and Chip Scale Packages. The underfill material 30 is applied to the electronic component 20 prior to shipment of the surface mount package 10 and is generally in the form of a high viscosity, or no-flow liquid, gel, paste, film, or solid. The underfill material can be suitably tailored such that it is reworkable or non-reworkable (e.g., depending upon a customer's preference). Furthermore, the underfill material 30 can be loaded with filler or non-filled organic polymers of such chemical nature as epoxies, acrylics, etc.; and are generally thermoset or thermoplastic in nature.

Application of the underfill 30 can be to a single package 10 or multiples of packages on strips, tapes, reels, or other carriers, prior to singulation. Moreover, the underfill application can be effected via a plurality of techniques, such as for example, preforms, controlled dispense, screen printing, stencil printing, transfer molding, cavity molding, injection molding, tape, and transfer film. The technique selected can be relative to a format of component fabrication and manufacturing and also on physico-chemical characteristics of the underfill material 30. The underfill 30 can be applied to the package 10 to a predetermined height. Then, the package 10 can be singulated and packaged in individual carriers for shipment to a customer. Accordingly, the subject invention facilitates a customer's process of attaching a surface mount package to a substrate while mitigating the need for carrying out an additional underfill process at the customer's site.

A top view of a surface mount package 40 is shown in FIG. 2 having a pre-applied, edge locking type underfill 50, in accordance with an aspect of the present invention. The surface mount package 40 has a plurality of electrical contacts 60 (e.g., solder balls), which are formed on a surface of a die 70. The solder balls 60 act as securing material to facilitate the package 40 being attached (e.g. electrically connected) to a carrier or substrate, such as a printed wiring board or printed circuit board (not shown). The solder balls 60 can be an alloy of at least two metals selected from the group including tin, bismuth, nickel, cobalt, cadmium, antimony, indium, lead, silver, gallium, aluminum, germanium, silicon, gold, etc.; and can be eutectic or non-eutectic. Further, there is a trend in the industry to limit the utilization of lead in manufactured products, due to the toxicity of lead. Thus, the surface mount packages of the present invention can be employed having interconnects with substantially lead-free contacts.

For example, the electrical contacts 60 may include plurality of polymer contacts (e.g., polymer balls) and/or a plurality of metallic contacts (e.g., copper balls) thereon. In addition to limiting the utilization of lead, employing both polymer and metallic contacts facilitates improved reliability of an electronic device. For instance, the polymer balls are employed to improve mechanical compliance of the surface mount package to the substrate. However, polymer balls generally have poor thermal performance. Thus, the metallic balls are included on the package to improve thermal conduction from the package to the substrate. Accordingly, a surface mount package having polymer and metallic contacts improves both mechanical stresses and thermal conductivity of the interconnection, which leads to improved joint reliability and thus, improved total reliability of the electronic device.

The polymer ball can be composed of a polymer core of a size suitable for a desired application, coated with a copper layer and a solder layer. The copper and solder layers are employed to facilitate electrical contact via solder attachment to input/output pads of an integrated circuit element. The metallic ball can be composed of a solid metallic core (e.g., copper) with a solder layer coating to facilitate electrical contact with the integrated circuit. The metallic ball also facilitates improved standoff of the electrical device, due to a high melting temperature of the metal employed. The solder coating on the polymer and metallic balls acts as a mechanical bond to hold the balls in electrical contact with interconnecting surfaces of the integrated circuit element, as well as maintains a substantially oxide-free surface until interconnection.

Although the solder balls are depicted in a substantially uniform, grid-like pattern throughout the figures, it is to be appreciated that the solder balls can be arranged in any pattern. Furthermore, it is to be appreciated that although the subject invention is described with respect to solder balls and electrically conductive leads as primary forms of electrical contacts, the subject invention is not intended to be limited to such types of contacts. Thus, any type(s) of electrical contacts suitable for implementation in accordance with the subject invention are contemplated and are intended to fall within the scope of the hereto appended claims.

Underfill material can be applied to an electronic component such that the underfill substantially covers a surface of the component having attachment material thereon. Additionally, many advantages can be appreciated with various configurations of the underfill material. In FIG. 2, for example, the underfill 50 is located around an outer perimeter of the package 40. Thus, in this example, the underfill 50 substantially covers solder balls 60 located around the outer perimeter of the package 40. As can be appreciated, the viscosity of the underfill material 50 provides for conformal distribution thereof about a desired location. Solder balls 60 located in an inner region of the package are left substantially uncovered by the underfill 50. The uncovered (or exposed) solder balls 60 facilitate self alignment of the package 40 with corresponding components on the substrate. When the package and substrate assembly is heated and the solder reflows, surface tension of the exposed solder facilitates aligning the component into a desired position.

FIG. 3 illustrates a perspective view of an edge locking type underfill as described above with respect to FIG. 2. The exaggerated size of the surface mount packages, particularly the solder balls and the thickness of the dies and underfill layers, is shown herein for illustration purposes only and one skilled in the art could readily determine appropriate sizes and amounts of solder and underfill for carrying out the subject invention with respect to particular package applications. An additional benefit of the configuration depicted in FIGS. 2-3, is that cost savings are realized by dispensing underfill 50 such that the underfill is located around an outer perimeter of a die 70. In many conventional applications, underfill is generally dispensed such that the underfill substantially fills an area within a component-to-substrate gap and, additional underfill is sometimes dispensed along a complete assembly periphery. In contrast, in the configurations described with respect to FIGS. 2-3 and in subsequent configurations, less underfill material is dispensed/employed in connection with the package.

FIGS. 4-5 illustrate another type of edge locking underfill in accordance with an aspect of the present invention. Surface mount packages are manufactured in various styles and shapes. In some instances, a package, and/or a solder ball configuration, is shaped such that underfill material can be dispensed along an outer perimeter of the package without encroaching onto the solder balls. In FIGS. 4-5, a surface mount package 100 is illustrated that is larger in size than the package 40 in FIGS. 2-3. Thus, underfill 110 can be applied about a perimeter of a die 120, and an array of solder balls 130 is left substantially uncovered by the underfill 110. Accordingly, more options are available with respect to the type of material that can be utilized for the underfill 110. Further, the more solder balls 130 left uncovered, the more likely the solder balls 130 will connect to a substrate, thereby facilitating positioning and self alignment of the package 100 with the substrate. This configuration also provides an option to apply underfill to the package 100 prior to the formation of the solder balls 130 on the die 120.

Turning now to FIGS. 6-7, another type of edge locking underfill is depicted. A package 200 includes underfill 210 that is placed around an outer perimeter of a die 220. The underfill 210 substantially covers solder balls 230 located around the outer perimeter of the die 220, while leaving solder balls 230 located in an inner region of the package 200 uncovered, similar to the configuration of FIGS. 2-3 above. However, in this embodiment, the underfill 210 includes cavities 240 to permit for the escape of moisture, solvents and/or gases during an assembly operation. As a result, formation of voids, which could potentially compromise integrity of the underfill 210, is mitigated. Additionally, because the underfill 210 is applied such that solder balls 230 located in an inner region of the package 200 are uncovered, self alignment of the package 200 with respect to the substrate is facilitated.

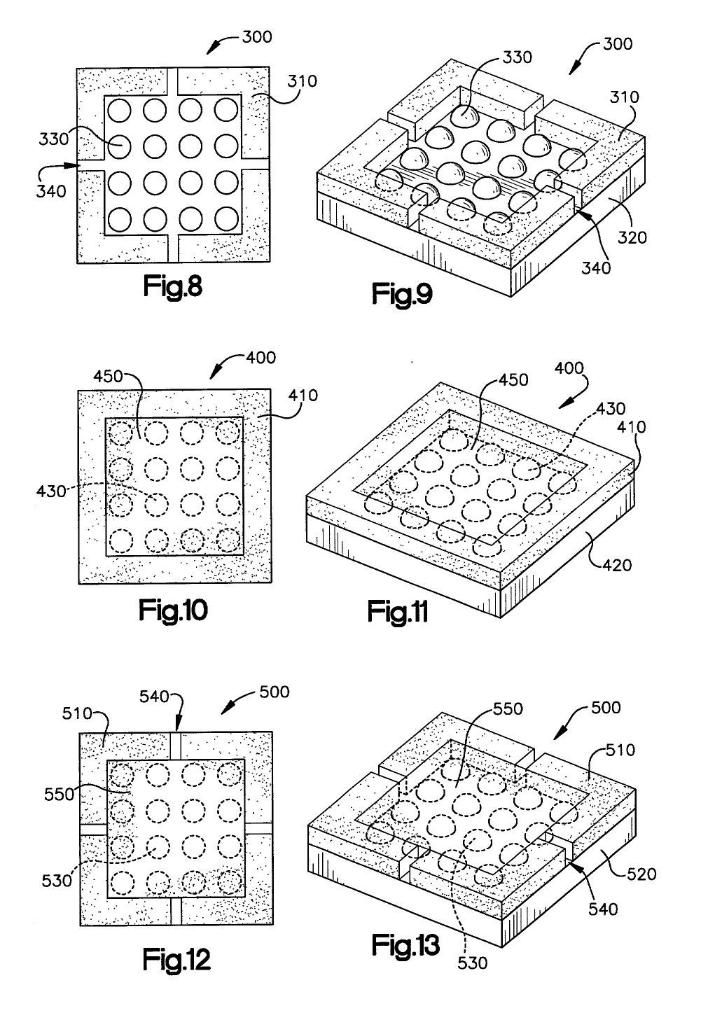

FIGS. 8-9 illustrate another example of an edge locking underfill having cavities in accordance with the subject invention. Similar to FIGS. 4-5, a surface mount package 300 is illustrated which is larger in size than the packages 40 and 200 in FIGS. 2-3 and 6-7, respectively. Thus, underfill 310 is applied around the perimeter of a die 320, and an array of solder balls 330 is left substantially uncovered by the underfill 310. Accordingly, package alignment is facilitated as well as an option to utilize a greater variety of underfill materials is provided by such configuration. Further, the underfill in FIGS. 8-9 includes cavities 340, which allow for the escape of moisture, solvents, and/or gases produced during the assembly, or reflow, process.

Although, the cavities provided in the underfill materials, described with reference to FIGS. 6-9, display important qualities, there exist applications in which cavities are not desired. This can be the case where a viscosity of the underfill material is such that it does not afford for gaps in the material. Another instance in which cavities are undesirable is when the assembly, or reflow, process and/or underfill material does not involve evolution of moisture, solvents, and/or gases, and thus, providing for such cavities would result in an unnecessary increase in time, cost, and/or process steps.

FIGS. 10-13 illustrate dam and fill type underfills in accordance with an aspect of the present invention. The dam and fill type underfills include an edge locking underfill, similar to those described above, and in addition, a second type of underfill in an inner region of the package, which is not covered by the edge locking underfill. Such a two-tier underfill process provides different levels of compensation for coefficients of thermal expansion, and additionally, can act as a heat sink. The second type of underfill further allows for application of at least two different underfill materials in the surface mount package. The first type of underfill applied about the perimeter has at least one preferred characteristic, and facilitates the creation of a dam like structure around the component. The second material has at least one different preferred characteristic, such as for example increased thermal conductivity. Fluxing underfills can also be selected to facilitate electrical connectivity being established between the package and mounting surface. The first and second underfill layers provide the package with a substantially flat surface, which facilitates placement of the package on a substrate.

Referring now to FIGS. 10-11, a surface mount package 400 is illustrated having a first underfill material 410 disposed, deposited, or otherwise placed around an outer perimeter of a die 420. The first underfill material 410 is applied in a manner such that a solder ball array 430 is left substantially uncovered by the first underfill 410. Furthermore, the first underfill 410 creates a dam-like structure as shown in FIG. 11. A second underfill material 450 is then applied to the package 400 to substantially fill the dam-like area created by the first underfill 410.

Referring now to FIGS. 12-13, another surface mount package 500 having a dam and fill type underfill comprising a first underfill 510 and a second underfill 550 is depicted. However, in this example, the first underfill 510 has at least one cavity 540 within the first underfill layer 510 to allow for the escape of moisture, solvents, and/or gases produced during assembly, or reflow, processes. Although FIGS. 10-13 illustrate one type of surface mount package being employed with the dam and fill type underfill, it is to be appreciated that the dam and fill underfill can be applied on any suitable style or shape package.

The examples above have been illustrated with an underfill layer that is substantially contiguous around an outer perimeter of a package. However, it is to be appreciated that the underfill layer can also be applied on one or any number of sides of the package and is contemplated as falling within the scope of the hereto appended claims.

Once a surface mount package has been assembled and an underfill layer disposed, deposited, or otherwise placed thereon, the package is shipped to a customer where the package is attached to a substrate. The customer aligns the package with the substrate such that electrical contacts (e.g., solder ball array) on the package corresponds with components on the substrate. The underfilled package is positioned and held onto the substrate by at least one of: inherent tackiness of the underfill material on the package, placement pressure, heat, or application of other suitable agents. The process of attaching the package to the substrate can be accomplished in several different manners, with or without heat and pressure. Some examples of such methods include: placing the package after solder paste is printed; placing the package without solder paste; applying flux to the substrate, then placing the package; and applying flux to the component prior to placement.

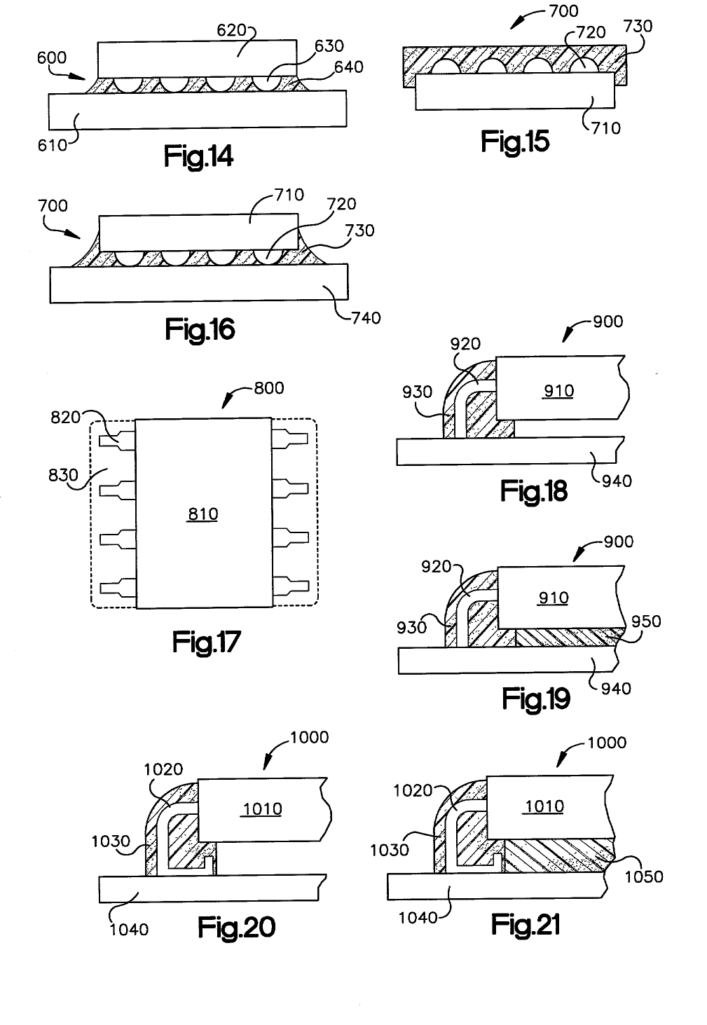

FIG. 14 illustrates a surface mount package 600 attached to a substrate, such as a printed wiring board or printed circuit board, 610. The package 600, comprising a die 620 having a solder ball array 630 and a pre-applied underfill layer 640 thereon, is connected to the substrate 610 through a heat radiation or conduction soldering process, which brings printed circuit assemblies into contact with heated air to melt the solder 630. Solder reflow is completed in several stages or zones of different temperature. First, the heated air increases the board 610 and component 600 temperature, then, activates the flux, and reflows the solder “printed” on the board surface, onto which components have been attached. Upon melting in a high temperature zone, the solder wets the termination areas and, after cooling, establishes a solder joint.

Common reflow heating methods include infrared radiation, forced hot air convection, and thermal conduction. During an infrared radiation process, radiant infrared energy is absorbed by materials of the device causing the device to heat; thus effecting reflow of solder. In a forced hot air convection process, air is heated and circulated in a respective zone. The heat is transferred to a device via the heated air, causing the device and electrical contacts (e.g., solder balls) to heat and cause reflow of the solder. The thermal conduction process involves a device being moved across a surface of a progressive series of heated platen. Heat is transferred through surface contact, allowing the electrical contacts (e.g., solder balls) to heat and reflow.

The solder 630 interconnection and underfill 640 spreading and curing can take place concurrently or sequentially. Generally, the underfill 640 is applied to the package 600 prior to a reflow process, and can be selected to have a melting temperature substantially coincident to a melting temperature of the electrical contacts (e.g., solder balls) 630. Thus, during reflow, the underfill 640 cures concurrently with melting of solder 630. The temperature of heat applied during reflow is such that the components of the circuit board are properly attached, which can be about 20-25 degrees above the melting point of the type of solder employed. This is done to accommodate for different size components, as well as, differences in the heat capacity of the components on the board. However, the underfill can also be spread and cured sequentially, as a separate step, after the solder reflow process.

It is to be appreciated that the underfill application methods, package placement methods, heating methods, etc. have been presented herein for sake of illustration and description only. As such, these methods are not intended to be exhaustive or to limit the invention to the methods disclosed.

FIG. 15 illustrates yet another configuration in which underfill can be applied to a package 700. A die 710 with an array of electrical contacts (e.g., solder balls) 720 is provided. Underfill material 730 is dispensed such that the underfill 730 overhangs along sidewalls of the die 710 and extends to about the middle of the package 700. The underfill 730 can substantially cover a top surface of the die 710, the top surface being the surface with the solder balls 720 thereon. Alternatively, the underfill 730 can be applied to the top surface of the die 710 in any manner, such as those described above with respect to FIGS. 2-13. When the package 700 is aligned with a substrate 740 and the assembly is heated, the additional underfill 730 spreads to create a filet around edges of the interconnection, as shown in FIG. 16. This additional underfill 730 provides further reinforcement to the device.

Turning now to FIG. 17, another example of a surface mount package having pre-applied underfill is illustrated in accordance with an aspect of the present invention. Rather than employing solder balls as attachment material, a package 800 is illustrated having electrically conductive leads 820 as attachment material. However, the basic principle is the same. Underfill material 830 is applied to the leads (e.g., on the underside) prior to shipping. In addition to the benefits of having pre-applied underfill as discussed above, the underfill 830 mitigates handling damage to the package, for example, to gull wing components, component leads that flare outward, and J-leads.

FIGS. 18-19 illustrate a TSOP (Thin Small Outline Package) 900 having pre-applied underfill. The TSOP 900 comprises an electronic component 910 with electrically conductive leads 920 extending in a downward direction from the body of the component 910. Accordingly, the leads 920 are alignable with, and solderable to, electrical terminations on a substrate 940. TSOP packages are generally, by design, low stand off packages whose leads are made of such materials as Cu-alloys and Nickel—Iron alloys. The nature of the lead materials (e.g., Nickel, Cu, and Iron), the shape of the formed leads, and the design feature essentially reduce or eliminate any compliance. Thus, when there is a mismatch between the CTE of the package 900 and the CTE of the substrate 940, stress is placed at joints connecting the leads 920 to the substrate 940. In a thermal cycling environment, these solder joints are inclined to fracture. In order to mitigate fracture of the solder joints, the leads are reinforced with underfill material. Stress caused by the CTE mismatch is then distributed into the underfill. FIG. 19 further illustrates a second underfill material 950 applied between the component 910 and the substrate 940. The second underfill material 950 can serve to reinforce a connection between the package 900 and the substrate 940. Moreover, if the second underfill material 950 is thermally conductive, the underfill 950 can provide heat dissipation for the electrical device.

A J-lead, as shown in FIGS. 20-21, can also be packaged with pre-applied underfill. A J-lead 1000 is a lead, extending from an electronic component 1010, which is rolled under the package. A side view of the formed lead resembles the shape of the letter J. Underfill 1030 is pre-applied to leads 1020 of the package 1000 in a manner similar to that described above. The underfill 1030, again, acts to reinforce the leads and mitigate the fracture of solder joints during thermal cycling. A second underfill material 1050 can be pre-applied to the component 1010 and will provide additional benefits, as discussed above. Further, in FIGS. 19 and 21, having the second underfill material applied to the component will provide the package with a substantially flat surface to mount to a substrate.

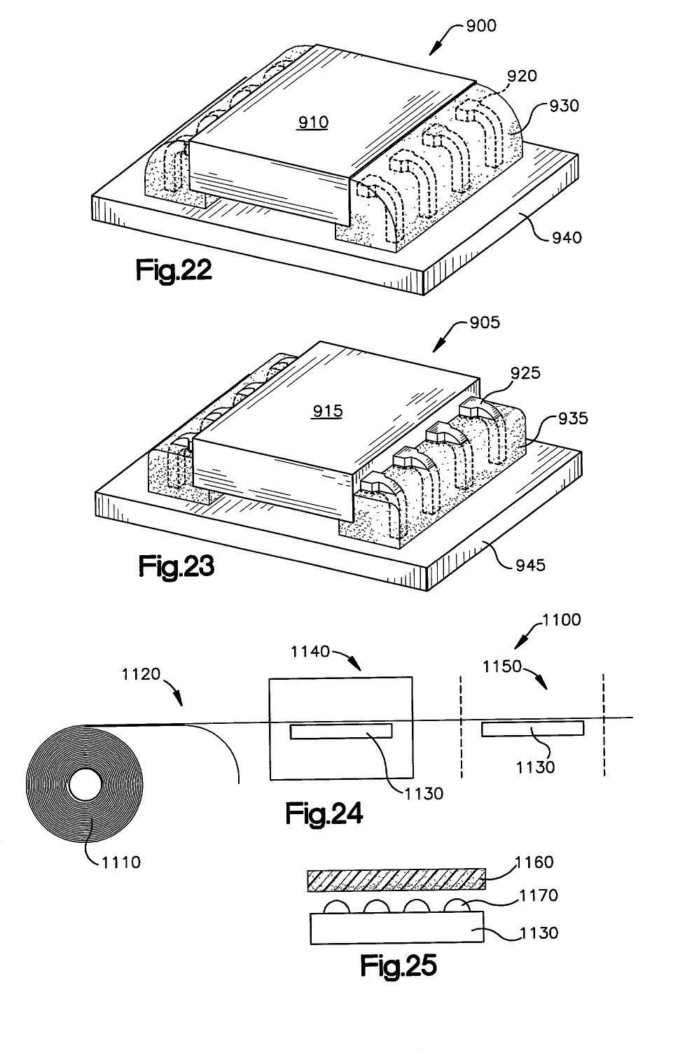

For illustration purposes, the structure described in FIG. 18 is shown in perspective view in FIG. 22. The surface mount package 900 comprises a die 910 with a plurality of leads 920 extending from the body of the die 910. The leads 920 have underfill material 930 applied to a predetermined thickness to absorb the stress of thermal cycling and also, to prevent handling damage to the leads 920 during shipping. The underfills in FIGS. 18-22 have been depicted as substantially covering the leads of the package, however, the underfill can be also be applied as illustrated with respect to FIG. 23. In FIG. 23, an example of a surface mount package 905 is depicted in accordance with an aspect of the present invention. The surface mount package 905 has a plurality of leads 925 extending from a body of a die 915. Underfill 935 is applied to the leads 925 such that at least a portion of the leads 925 is not enclosed by underfill 935. However, the underfill 935 is applied to other portions of the leads 925, which are joined to a substrate 945, to mitigate fracture of the joints.

Although, FIGS. 18-23 have been described as having TSOP or J-lead configurations, it is to be appreciated that any similar surface mount package can be packaged with pre-applied underfill and will experience similar benefits described herein. For example, pre-applied underfill can be employed in integrated circuits which include optical functions in addition to electrical functions. Thus, underfill material can be applied to a surface mount package having a plurality of electrically conductive leads and at least one optical lead prior to shipment. Pre-applied underfill is employed in the surface mount package to compensate for differing CTEs of the package and a substrate. Moreover, underfill material can act as a cladding for the optical leads. When the encapsulating underfill has a relatively low index of refraction, it serves the same function as a cladding, that is, the underfill facilitates the trapping of light within the optical lead core material by internal reflection. If the underfill has the same index of refraction as the optical lead core material, light can escape from regions of the optical lead where the cladding has been removed; however, the light will have low escape angles which will keep it trapped within the underfill as stated above.

As an alternative to liquid based underfill materials, a tape, or film, can be employed to reinforce a connection between a package and substrate and to absorb stress caused by thermal cycling. FIG. 24 illustrates an example of a film application process 1100 in accordance with an aspect of the present invention. A reel of film 1110 is provided having two protective coatings located on either side of the film 1110. At 1120, one of the protective coatings is peeled from the film 1110 and the film 1110 is positioned over a package 1130. The package 1130 and film 1110 assembly is then processed by applying vacuum, heat, pressure, or other suitable method(s) to facilitate application of the film 1110 to the package 1130. The film 1110 is attached such that a region between the film 1110 and the package 1130 is substantially free of air. Then, at 1150, the film 1110 is cut to a length corresponding to the length of the package 1130.

A package employing a film type underfill is depicted in FIG. 25. Here, the film underfill 1160 is shown prior to undergoing the attachment process 1140. The film underfill 1160 can substantially cover a top surface of the package 1130, the top surface being the surface with an array of solder balls 1170 disposed, deposited, or otherwise placed thereon. Alternatively, the film underfill can be applied in any manner as described above with respect to the liquid based underfills.

FIG. 26 illustrates a film process 1200 similar to that described in FIG. 24. A reel of film 1210 is supplied, the film 1210 having two protective coatings thereon. A punching operation 1220 is then included, in which holes are punched in the film 1210 to provide for a plurality of solder balls. The holes can be punched such that they accommodate substantially all the solder balls on the component or no more than a predetermined number of solder balls. The punching operation 1220 may be performed via mechanical, laser, or any other suitable means. Although the punching operation 1220 is depicted in FIG. 26 as being in line with an application process 1250 and a cutting process 1260, it is to be appreciated that the punching process 1220 can be performed off-line, at a separate stage. Further, as an alternative to the punching process 1220, film can be supplied with pre-punched holes. However, an alignment stage would subsequently be desired to position the pre-punched holes with the location of the solder balls.

After holes have been punched in the film 1210, at least one of the protective coatings is peeled from the film 1210 and positioned over a package 1240 in a manner as described above. The package 1240 and film 1210 assembly is subsequently processed such that the region between the film 1210 and the package 1240 is substantially free of air. Then, at 1260, the film 1210 is cut to a length corresponding to the length of the package 1240.

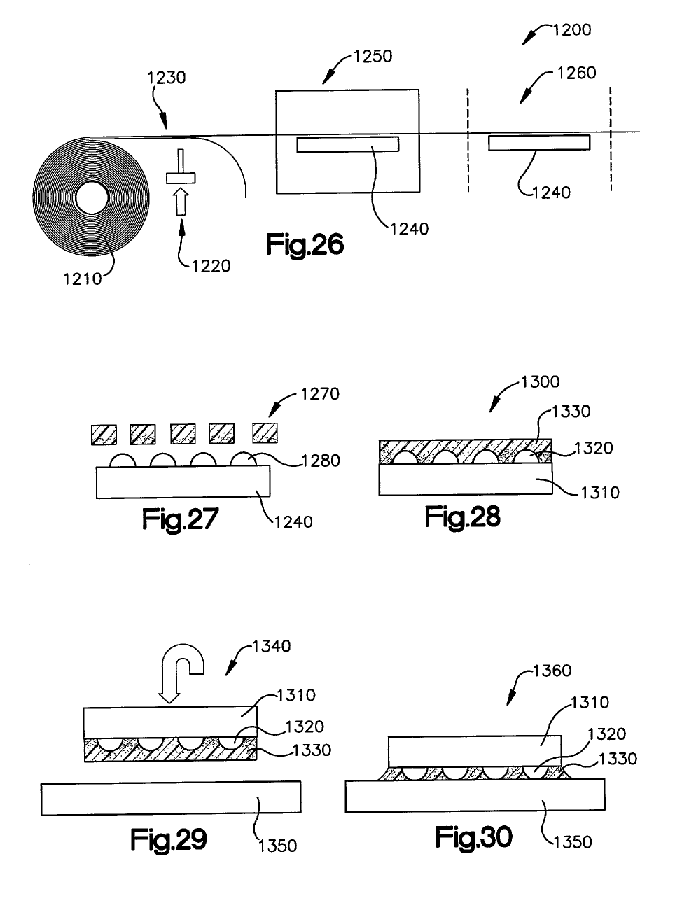

FIG. 27 is an illustration of package 1240 with a punched film underfill 1270. The film underfill 1270 is punched so as to expose at least a portion of an array of solder balls 1280. Although, the underfill 1270 is applied such that the area between the underfill 1270 and the package 1240 is substantially free of air, a gap is shown in FIG. 27 for illustration purposes. Further, the more solder balls 1280 left uncovered, the more likely the solder balls 1280 will attach to a substrate, and thus, facilitate positioning and self alignment of the package 1240. This configuration also leaves open an option to apply underfill to the package 1240 prior to the formation of electrical contacts (e.g., solder balls) 1280 on the package 1240.

FIGS. 28-30 depict a sequence of operations for connecting a package with pre-applied underfill to a printed wiring board, or other substrate. In FIG. 28, a surface mount package 1300 is provided. The package 1300 comprises a die 1310 to which a plurality of solder balls 1320 are applied, the solder balls 1320 acting as an electrical connection for the package 1300. An underfill layer 1330 is disposed, deposited, or otherwise placed on the package in a manner and of a type suitable for its application.

In FIG. 29, the package 1300 is turned over such that the solder balls 1320 can be aligned with corresponding electrical terminations (not shown) on a substrate 1350, the reflow process is initiated. During the reflow process, a preferred heating method is applied to the package 1300 and substrate 1350 assembly until the solder balls 1320 have formed a connection with the terminations on the substrate 1350. The underfill 1330 is cured concurrently with reflow of the solder 1320 and the resulting device is illustrated in FIG. 30.

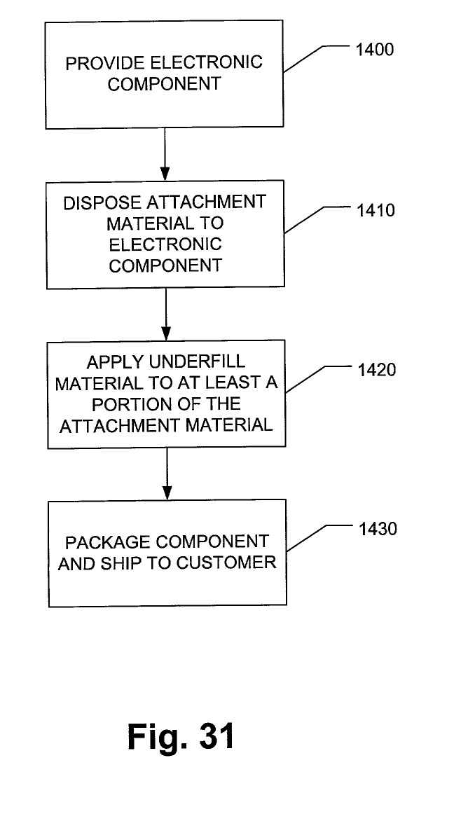

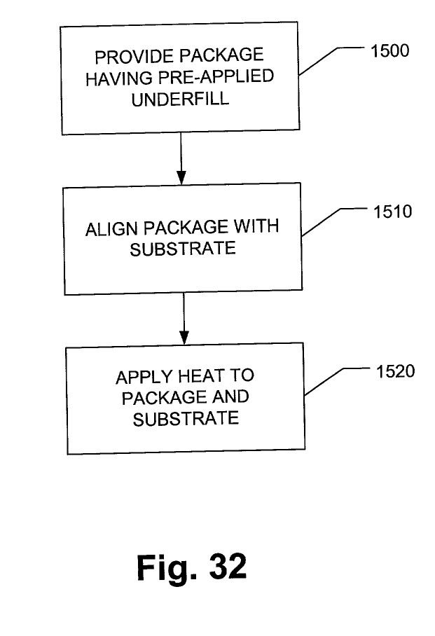

In view of the foregoing structural and functional features described above, methodologies in accordance with various aspects of the present invention will be better appreciated with reference to FIGS. 31-32. While, for purposes of simplicity of explanation, the methodologies of FIGS. 31-32 are shown and described as executing serially, it is to be understood and appreciated that the present invention is not limited by the illustrated order, as some aspects could, in accordance with the present invention, occur in different orders and/or concurrently with other aspects from that shown and described herein. Moreover, not all illustrated features may be required to implement a methodology in accordance with an aspect the present invention.

FIG. 31 illustrates a methodology for fabricating a surface mount package having pre-applied underfill. The methodology begins at 1400 where an electronic component is provided. Then, at 1410, attachment material, such as solder balls or lead wires, is coupled to the electronic component. Thus, the electronic component becomes a surface mount package and can be one of a Ball Grid Array, gull wing, J-leaded, and Chip Scale Package. Conventionally, at this point, the package is singulated and packaged in individual carriers for shipment. The customer receiving the package is then faced with the task of reducing the stress present between the attachment material and the substrate during a reflow process. This task generally involves the customer obtaining additional tools, man-power, process steps, and potential exposure to hazardous vapors and fumes.

However, in accordance with an aspect of the present invention, at 1420, underfill material is applied to at least a portion of the attachment material at the supplier level. The application can be to a single package or multiple packages and can be carried out via a plurality of techniques, such as, preforms, controlled dispense, screen printing, stencil printing, transfer molding, cavity molding, injection molding, tape, and transfer film. The technique selected is relative to the format of component fabrication and manufacturing and also on physico-chemical characteristics of the underfill material. The underfill is applied to the package to a predetermined height or in a predetermined volume. Then, at 1430, the package is singulated and packaged in individual carriers for shipment to a customer. Accordingly, the customer's normal process of attaching the package to a substrate can be employed without an additional underfill process.

FIG. 32 illustrates a methodology for using a surface mount package having pre-applied underfill. This methodology begins at 1500 where a surface mount package having pre-applied underfill is provided. The package is then aligned with a substrate at 1510. Here, attachment material (e.g., solder balls, lead wires) corresponds with electrical terminations on the substrate. If the underfill is configured in a manner such that at least a portion of the attachment material is left uncovered by the underfill, greater positioning and self-alignment of the package with respect to the substrate is facilitated. Then, at 1520, heat is applied to the package and substrate to reflow the attachment material. During the reflow operation, an electrical connection between the package and substrate is obtained. Further, if the underfill material selected is somewhat coincident to the melting temperature of the attachment material, the underfill can substantially cure concurrently with the reflow of the attachment material. Accordingly, underfill application and curing operations are mitigated for the customer.

It is to be appreciated that the packages and methodologies of the subject invention as described herein have wide applicability. The surface mount packages of the subject invention can be employed for example in numerous types of commercial and industrial electronic devices (e.g., cellular telephones, computers, personal data assistants, cameras, facsimile machines, toys, electronic games, memory cards . . . ). Moreover, the methodologies of the subject invention can be employed in connection with processes associated with fabricating packages related to such devices.

What has been described above includes exemplary implementations of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims.

What is claimed is:

1. A surface mount package, comprising:
an electronic component having a first side and a second side, the first side including a plurality of electrical contacts thereon; and
underfill material applied along at least a portion of the first side of the electronic component prior to shipping.

2. The surface mount package of claim 1, the electrical contacts comprising a plurality of solder balls.

3. The surface mount package of claim 1, the electrical contacts comprising a plurality of polymer balls and a plurality of metallic balls.

4. The surface mount package of claim 1, the electrical contacts comprising a plurality of electrically conductive leads.

5. The surface mount package of claim 4, the electrical contacts further comprising at least one optical lead.

6. The surface mount package of claim 4, the underfill material facilitating the trapping of light within the at least one optical lead.

7. The surface mount package of claim 1 employed in an electronic device.

8. A surface mount package, comprising:
an electronic component having a first side and a second side, the first side including a plurality of electrical contacts thereon; and
a first underfill material applied along at least a portion of a perimeter of the first side prior to shipping.

9. The surface mount package of claim 8, the first underfill material being contiguous along the perimeter of the first side.

10. The surface mount package of claim 9, the first underfill material forming a dam-like structure along the perimeter of the first side.

11. The surface mount package of claim 10, a second underfill material filling at least a portion of an inner area created by the dam-like structure.

12. The surface mount package of claim 11, the second underfill material facilitating dissipation of heat from the package.

13. The surface mount package of claim 11, the first underfill material and the second underfill material having different coefficients of thermal expansion (CTE).

14. The surface mount package of claim 8, the first underfill material having at least one cavity formed therein to facilitate egress of moisture or gas.

15. The surface mount package of claim 8, the first underfill overlapping at least an outside perimeter row of the electrical contacts.

16. The surface mount package of claim 8, the electrical contacts comprising a plurality of solder balls.

17. The surface mount package of claim 16, the plurality of solder balls comprising a plurality of solder coated polymer balls and a plurality of solder coated metallic balls.

18. The surface mount package of claim 8, the electrical contacts comprising a plurality of electrically conductive leads.

19. The surface mount package of claim 18, the electrical contacts further comprising at least one optical lead.

20. The surface mount package of claim 8, the first underfill material overlapping at least one edge of the first side, such that the overlapping underfill creates a filet between the package and a substrate during a reflow process.

21. The surface mount package of claim 20, the first underfill material substantially covering the plurality of electrical contacts.

22. The surface mount package of claim 21, the first underfill material being substantially contiguous along the perimeter of the first side.

23. The surface mount package of claim 8, the first underfill material being amenable to rework.

24. The surface mount package of claim 8, the first underfill applied in a gel, paste, tape, film, or solid form.

25. A surface mount package, comprising:
an electronic component having a plurality of leads extending from a body of the electronic component; and
a first underfill applied to at least one of the plurality of leads, the first underfill material being applied prior to shipping of the package.

26. The surface mount package of claim 25, a second underfill material applied to a first side of the body, the first side of the body being the side coupled to a substrate during a reflow process.

27. The surface mount package of claim 25, the second underfill facilitating dissipation of heat from the surface mount package.

28. The surface mount package of claim 25, the electronic component being one of a thin small outline package (TSOP) and small outline J-lead (SOJ) package.

29. The surface mount package of claim 25, the first underfill applied in a gel, paste, tape, film, no-flow liquid, or solid form.

30. A method for fabricating a surface mount package, comprising:
employing an electronic component having a first side and a second side;
disposing attachment material to the first side; and
applying a first underfill material to the first side of the electronic component, the first underfill material being applied prior to shipment of the package.

31. The method of claim 30, the attachment material being a plurality of solder balls.

32. The method of claim 30, the attachment material being a plurality of wire leads.

33. The method of claim 30, further comprising applying a second underfill material to the package, the second underfill material facilitating improved thermal conductivity and dissipation of heat.

34. The method of claim 30, further comprising packaging the surface mount package having underfill material applied thereon and shipping the package to a customer.

35. A method for applying a film underfill to a surface mount package, comprising:
positioning the film underfill on the surface mount package;
attaching the film underfill to the surface mount package such that the area between the film underfill and the surface mount package is substantially free of air;
cutting the film underfill to a size corresponding to a size of the surface mount package; and
shipping the surface mount package with the film underfill applied thereon.

36. The method of claim 35, the attaching being at least one of applying a vacuum, heat, and pressure.

37. The method of claim 35, further comprising punching holes in the film underfill to accommodate electrical contacts on the surface mount package.

38. The method of claim 35, the film underfill having pre-punched holes to accommodate electrical contacts on the surface mount package.

39. The method of claim 38, the positioning including aligning the pre-punched holes with the electrical contacts.

40. A method for connecting a surface mount package with a substrate, comprising:
employing a surface mount package with pre-applied underfill thereon;
aligning attachment material of the surface mount package with electrical terminations of the substrate; and
applying heat to the surface mount package and the substrate, such that the heat facilitates connection of the attachment material with the electrical terminations.

41. The method of claim 40, further comprising, curing the underfill material concurrently with the application of heat to the package and the substrate.

42. A surface mount package, comprising:
an electronic component having a plurality of electrical contacts thereon; and
a pre-applied underfill material forming a wall along at least a portion of a perimeter of the package, the underfill material upon curing partly compensating for thermal mismatch between the package and a substrate.

43. The surface mount package of claim 42 employed in a cellular telephone.

44. The surface mount package of claim 42 employed in a computing device.

45. The surface mount package of claim 42 employed in a camera.

46. The surface mount package of claim 42 employed in an electronic device.

47. A surface mount package, comprising:
means for providing an electrical connection between the surface mount package and a surface; and
means for compensating for thermal mismatch between the surface mount package and the substrate, the means for compensating being part of the package prior to shipping.
